(19) United States
(12) Patent Application Publication
(10) Pub. No.: US 2012/0118228 A1
(43) Pub. Date: May 17, 2012

(54) SAPPHIRE INGOT GROWER

(76) Inventors: Sang Hoon Lee, Gyeoungbuk (KR); Jae Hun Lee, Gyeoungbuk (KR); Soo Yui Kim, Gyeoungbuk (KR); Hyun Jung Oh, Gyeoungbuk (KR)

(21) Appl. No.: 13/297,023

(22) Filed: Nov. 15, 2011

(30) Foreign Application Priority Data
Nov. 15, 2010 (KR) 10-2010-0113238

(51) Int. Cl. C30B 15/14

(52) U.S. Cl. 117/217

(57) ABSTRACT

Provided is a sapphire ingot grower. The sapphire ingot grower includes a chamber, a crucible disposed in the chamber to contain alumina melt, a heater disposed outside the crucible to heat the crucible, and a heat supply unit disposed over an ingot growing within the crucible to apply heat to the ingot.

### CROSS-REFERENCE TO RELATED APPLICATION

This application claims under 35 U.S.C. § 119 to Korean Patent Application No. 10-2010-0113238, filed Nov. 15, 2010, which is hereby incorporated by reference in its entirety.

### BACKGROUND

Typically, in order to manufacture a sapphire wafer, a growth furnace charged with the raw material of high-purity alumina (Al₂O₃) is heated to or over 2,100 degrees Celsius to melt the raw material, and then an ingot boule, which has been grown into a single crystal through methods such as Czochralski Method (CZ Method), Kyropoulos Method, edge-defined flim-fed growth, or vertical-horizontal gradient freezing (VHGF), goes through a series of processes such as coring, grinding, slicing, lapping, heat treatment, and polishing.

In producing a sapphire single crystal, the bubble control and dislocation control have a serious effect on quality.

Dislocation may be measured by using an etching manner after crystal growth. Dislocation is generated by thermal stress, which is a temperature difference between inside and outside a crystal occurring during the crystal growth. Dislocation concentration may be controlled by controlling the thermal stress.

In the Kyropoulos Method according to the related art, an upper portion of a crystal is cold and a lower portion of the crystal is hot because of heating of side portions and the lower portion, resulting in a temperature gradient between the upper and lower portions. The temperature gradient generates thermal stress, which, in turn, generates dislocation. Therefore, an additional apparatus is necessary to control the thermal stress.

### SUMMARY OF THE INVENTION

Embodiments provide a sapphire ingot grower that can control dislocation quality of a sapphire single crystal.

In one embodiment, a sapphire ingot grower includes: a chamber; a crucible disposed in the chamber to contain alumina melt; a heater disposed outside the crucible to heat the crucible; and a heat supply unit disposed over an ingot growing within the crucible to apply heat to the ingot.

DESCRIPTION OF THE DRAWINGS

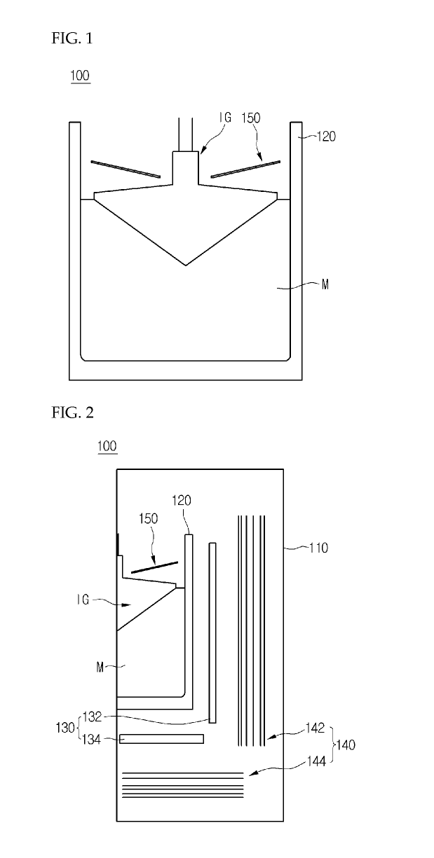

FIG. 1 is an example view of a sapphire ingot grower according to an embodiment.

FIG. 2 is a partially enlarged example view of the sapphire ingot grower according to the embodiment.

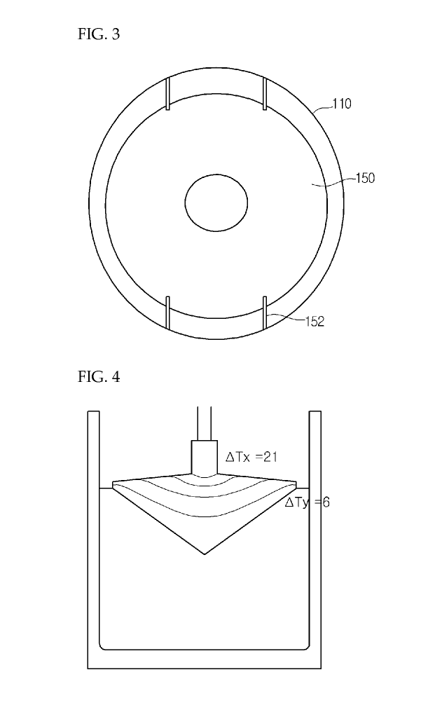

FIG. 3 is a plan example view of the sapphire ingot grower according to the embodiment.

FIG. 4 is an example view of a temperature variation between inside and outside a crystal according to a comparative example.

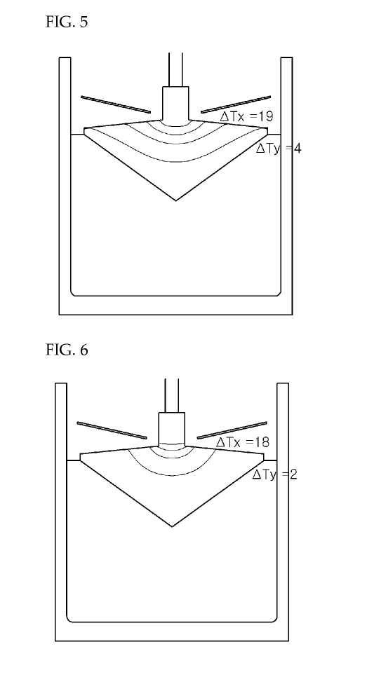

FIGS. 5 and 6 are example views of a temperature variation between inside and outside a crystal when the sapphire ingot grower is applied according to the embodiment.

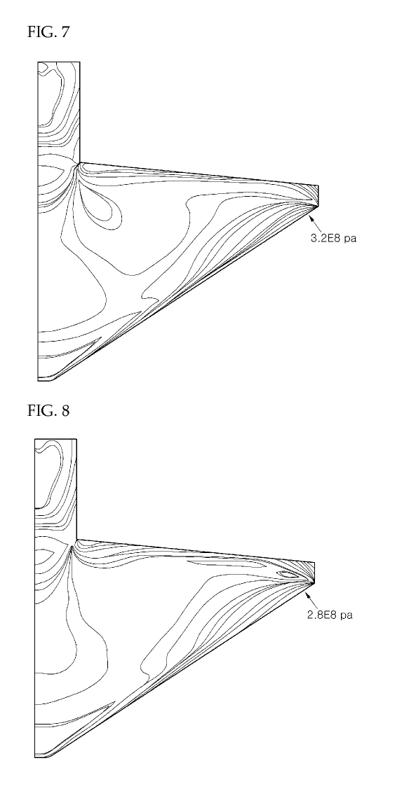

FIG. 7 is an example view illustrating thermal stress distribution according to the comparative example.

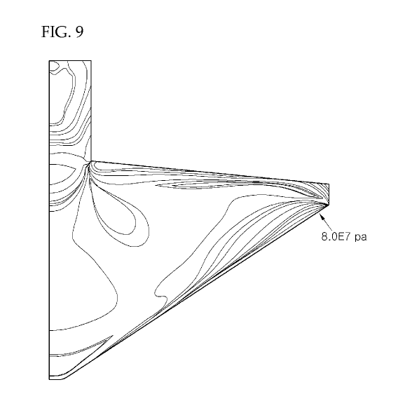

FIGS. 8 and 9 are example views of a thermal stress distribution when the sapphire ingot grower is applied according to the embodiment.

### DETAILED DESCRIPTION

In the description of embodiments, it will be understood that when a wafer, device, chuck, member, portion, area or surface is referred to as being ‘on’ or ‘under’ another wafer, device, chuck, member, portion, area or surface, the terminology of ‘on’ and ‘under’ includes both the meanings of ‘directly’ and ‘indirectly’. Further, the reference about ‘on’ and ‘under’ each element will be made on the basis of drawings. The sizes of the elements and the relative sizes between elements may be exaggerated for further understanding of the present invention and the size of each element does not entirely reflect an actual size.

### EMBODIMENTS

FIG. 1 is an example view of a sapphire ingot grower 100 according to an embodiment, FIG. 2 is a partially enlarged example view of the sapphire ingot grower 100 of the embodiment, and FIG. 3 is a plan example view of the sapphire ingot grower 100 of the embodiment.

Methods that may be applied to the sapphire ingot grower 100 according to the embodiment include CZ Method or Kyropoulos Method, but are not limited thereto.

The sapphire ingot grower 100 of the embodiment includes a chamber 110, a crucible 120 disposed in the chamber 110 to contain alumina melt M, a heater 130 disposed outside the crucible 120 to heat the crucible 120, and a heat supply unit 150 disposed over an ingot IG growing within the crucible 120 to apply heat to the ingot IG.

The chamber 110 provides a space in which predetermined processes for growing the sapphire ingot IG are carried out.

The crucible 120 is disposed in the chamber 110 to contain an alumina melt M. The crucible 120 may be formed of tungsten (W) or molybdenum (Mo), but the present disclosure is not limited thereto.

The heater 130 may include a side heater 132 and a lower heater 134, but the present disclosure is not limited thereto. The heater 130 may be a resistance heater or an induction heater, but the present disclosure is not limited thereto.

For example, when the heater 130 is a resistance heater, the heater 130 may be formed of graphite (C), tungsten (W), or molybdenum (Mo), but the present disclosure is not limited thereto.

When the heater 130 is an induction heater, a radio frequency (RF) coil (not shown) may be disposed at the heater 130, and the crucible 120 may be an iridium (Ir) crucible. The RF coil generates induced currents on a surface of the Ir crucible as a direction of high-voltage current flow is changed to RF. The Ir crucible generates heat resulting from stress on the surface of the crucible caused by a directional change of the induced currents, and may a function as a melting pool containing melted alumina having a high temperature.

The sapphire ingot grower of the embodiment may include a radiative insulating material 140 in the chamber 110 so that heat of the heater 130 is not released. The insulating material 140 may include a side insulation material 142 disposed at a side of the crucible 120 and a lower insulation material 144 disposed at a lower portion of the crucible 120, but the present disclosure is not limited thereto. The insulating material 140 may have a material and shape guaranteeing an optimal thermal distribution for the heater 130 and the crucible 120 and minimization of loss of the energy.

In general, when a single crystal is grown in a sapphire melt having a high temperature, a temperature variation occurs in an ingot and a thermal stress is generated.

According to the embodiment, the heat supply unit 150 such as an upper heater or a reflector is disposed over the sapphire ingot IG to reduce the temperature variation and control the thermal stress.

When the heat supply unit 150 is the upper heater, a size of the upper heater may increase in proportion to that of the ingot, and a maximum diameter of the upper heater may be equal to that of the ingot, but is not limited thereto.

The upper heater may be formed of tungsten or graphite, but the present disclosure is not limited thereto.

The upper heater may be a resistance heater, and heat generation may occur at the upper heater itself as electricity is applied from an electrode 152.

When the heat supply unit 150 includes the reflector which reflects heat generated by the chamber 110 upward from the ingot IG, the reflector may be formed of a highly reflective material such as molybdenum, but the present disclosure is not limited thereto.

The heat supply unit 150 may be placed horizontally to a surface of the alumina melt M or at an angle of about −30 degrees to about +30 degrees with respect to the surface of the alumina melt M so that heat is supplied to the ingot with efficiency.

FIG. 4 is an example view of a temperature variation between inside and outside a crystal according to a comparative example, and FIGS. 5 and 6 are example views of a temperature variation between inside and outside a crystal when the sapphire ingot grower is applied according to the embodiment.

For example, FIG. 5 illustrates the temperature variation between inside and outside the crystal with the reflector being installed, and FIG. 6 illustrates the temperature variation between inside and outside the crystal with the upper heater being installed and power of about 5 KW being applied.

According to the embodiment, when the reflector and the upper heater are installed, it is seen that the axial-direction temperature gradient of □ Ty and the horizontal-direction temperature gradient of □ Tx decrease.

FIG. 7 is an example view illustrating thermal stress distribution according to the comparative example, and FIGS. 8 and 9 are example views of a thermal stress distribution when the sapphire ingot grower is applied according to the embodiment.

For example, FIG. 8 illustrates the thermal stress with the reflector being installed, and FIG. 9 illustrates the thermal stress with the upper heater being installed.

As illustrated in FIGS. 8 and 9, the temperature gradient decrease caused by employing the heat supply unit 150 results in thermal stress difference. It is confirmed that a thermal stress value decreases under conditions described in FIGS. 8 and 9 when compared to that of the comparative example of FIG. 7, and dislocation concentration may be controlled thereby.

In the sapphire ingot grower according to the embodiment, the heat supply unit such as the heater or reflector may be provided over the sapphire single crystal to reduce the thermal stress by reducing the temperature variation between the upper and lower portions of the sapphire single crystal, thereby restricting the dislocation generation.

Also, according to the embodiment, limitations such as structure loss during the growth of the sapphire single crystal may be resolved by controlling the thermal stress. In addition, the dislocation concentration caused by the thermal stress may be controlled to grow the sapphire single crystal having high quality.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

The preferred embodiments should be considered in descriptive sense only and not for purposes of limitation. Therefore, the scope of the invention is defined not by the detailed description of the invention but by the appended claims, and all differences within the scope will be construed as being included in the present invention.

What is claimed is:

1. A sapphire ingot grower, comprising:
a chamber;
a crucible disposed in the chamber to contain alumina melt;
a heater disposed outside the crucible to heat the crucible; and
a heat supply unit disposed over an ingot growing within the crucible to apply heat to the ingot.

2. The sapphire ingot grower according to claim 1, wherein the heat supply unit is horizontally disposed on a surface of the alumina melt.

3. The sapphire ingot grower according to claim 1, wherein the heat supply unit is placed at an angle of about −30 degrees to about +30 degrees with respect to a surface of the alumina melt.

4. The sapphire ingot grower according to claim 1, wherein the heat supply unit comprises an upper heater generating heat.

5. The sapphire ingot grower according to claim 4, wherein the upper heater comprises an upper resistance heater.

6. The sapphire ingot grower according to claim 1, wherein the heat supply unit comprises a reflector reflecting heat generated in the chamber toward an upper side of the ingot.

7. The sapphire ingot grower according to claim 1, wherein the reflector comprises a molybdenum.
